(19) United States
(12) Patent Application Publication
(10) Pub. No.: US 2026/0057958 A1
(43) Pub. Date: Feb. 26, 2026

(54) INTERFACE CHIP AND TEST SYSTEM INCLUDING THE SAME

(71) Applicant: Samsung Electronics Co., Ltd., Suwon-si (KR)

(72) Inventors: Pilho LEE, Suwon-si (KR); Jongjin AN, Suwon-si (KR); Yongjeong KIM, Suwon-si (KR); Joosung YUN, Suwon-si (KR); Ungjin JANG, Suwon-si (KR); Hyuck-Soo JEON, Suwon-si (KR)

(73) Assignee: Samsung Electronics Co., Ltd., Suwon-si (KR)

(21) Appl. No.: 19/282,518

(22) Filed: Jul. 28, 2025

(30) Foreign Application Priority Data
Aug. 26, 2024 (KR) 10-2024-0114587

(51) Int. Cl. G11C 29/56; G11C 29/08

(52) U.S. Cl. CPC G11C 29/56016; G11C 29/08; G11C 2029/5602

(57) ABSTRACT

An interface chip includes a first interface circuit connected to a test device, the first interface circuit providing an interface for a first non-return to zero (NRZ) signal and a sideband signal for the test device; a second interface circuit connected to a device under test (DUT), the second interface circuit providing an interface for a second NRZ signal and a pulse amplitude modulation (PAM) signal for the DUT; and a conversion circuit connected to the first interface circuit and the second interface circuit, the conversion circuit providing conversion between the first NRZ signal and the second NRZ signal and between the first NRZ signal and the PAM signal based on the sideband signal.

### CROSS-REFERENCE TO RELATED APPLICATION(S)

This U.S. non-provisional application claims priority under 35 USC § 119 to Korean Patent Application No. 10-2024-0114587, filed on Aug. 26, 2024, in the Korean Intellectual Property Office, the disclosure of which is herein incorporated by reference in its entirety.

### BACKGROUND

Some example embodiments relate to interface chips and test systems including the same.

Memory devices may transmit or receive signals such as commands, addresses, and data to and from external devices. Signaling methods may be used to enhance the efficiency of input/output interfaces of memory devices.

A memory device may be tested as a device under test (DUT). This test may cause compatibility issues between a test device used to test the memory device and a memory device using a signaling method.

### SUMMARY

Some example embodiments provide an interface chip for providing interfacing between a test device and a device under test (DUT) and a test system including the same.

Some example embodiments of the inventive concepts provide an interface chip that includes a first interface circuit connected to a test device, the first interface circuit providing an interface for a first non-return to zero (NRZ) signal and a sideband signal for the test device; a second interface circuit connected to a device under test (DUT), the second interface circuit providing an interface for a second NRZ signal and a pulse amplitude modulation (PAM) for the DUT; and a conversion circuit connected to the first interface circuit and the second interface circuit and configured to provide conversion between the first NRZ signal and the second NRZ signal and between the first NRZ signal and the PAM signal based on the sideband signal.

Some example embodiments of the inventive concepts further provide an interface chip that includes a command address (CA) conversion circuit that receives a setting signal and a plurality of first CA signals which are non-return to zero (NRZ) signals from a test device, demultiplexes the plurality of first CA signals based on the setting signal, and outputs a second CA signal to a device under test (DUT) in response to demultiplexing by the CA conversion circuit; and a data conversion circuit that transmits a first data signal corresponding to the plurality of first CA signals and an error flag signal to the test device, the first data signal being an NRZ signal, or receives the first data signal, the error flag signal and an on-the-fly (OTF) signal from the test device, transmits a second data signal corresponding to the plurality of first CA signals to the DUT, the second data signal being a pulse amplitude modulated (PAM) signal, or receives from the DUT the second data signal, and provides conversion between the first data signal, the error flag signal, and the second data signal based on the OTF signal.

Some example embodiments of the inventive concepts still further provide a test system that includes a test device that transmits or receives a first non-return to zero (NRZ) signal for testing, and transmits a sideband signal for setting modes of operation; a device under test (DUT) that transmits or receives a second NRZ signal and a pulse amplitude modulation (PAM) signal; and an interface chip connected to the test device and the DUT, the interface chip providing conversion between the first NRZ signal and the second NRZ signal, and between the first NRZ signal and the PAM signal, based on the sideband signal.

### BRIEF DESCRIPTION OF DRAWINGS

FIG. 1 is a block diagram of an interface chip according to some example embodiments.

FIG. 2 is a diagram illustrating an interface chip according to some example embodiments.

FIG. 3 is a diagram illustrating a CA (command address) conversion circuit of FIG. 2 according to some example embodiments.

FIG. 4 is a diagram illustrating a CA conversion operation in 2:1 mode according to some example embodiments.

FIG. 5 is a diagram illustrating a CA conversion operation in 1:1 mode according to some example embodiments.

FIG. 6 is a diagram illustrating a data conversion circuit according to some example embodiments.

FIGS. 7 and 8 are diagrams illustrating conversion operations of a data conversion circuit according to some example embodiments.

FIG. 9 is a diagram illustrating a data conversion circuit according to some example embodiments.

FIG. 10 is a block diagram of a conversion circuit according to some example embodiments.

FIG. 11A is a diagram illustrating a first training circuit according to some example embodiments.

FIG. 11B is a diagram illustrating a second training circuit according to some example embodiments.

FIG. 12 is a block diagram of a conversion circuit according to some example embodiments.

FIG. 13 is a waveform diagram illustrating an example operation of an error conversion circuit of FIG. 12 according to some example embodiments.

FIG. 14 is a block diagram of a conversion circuit according to some example embodiments.

FIG. 15 is a block diagram of a first clock conversion circuit according to some example embodiments.

FIG. 16 is a flowchart illustrating a method of converting a CA signal of an interface chip according to some example embodiments.

FIG. 17 is a flowchart illustrating a method of converting a write data signal of an interface chip according to some example embodiments.

FIG. 18 is a flowchart illustrating a method of converting a read data signal of an interface chip according to some example embodiments.

FIG. 19 is a block diagram of a conversion circuit according to some example embodiments.

FIG. 20 is a diagram illustrating an operation of a self-training circuit of FIG. 19 according to some example embodiments.

FIG. 21 is a diagram illustrating a test system according to some example embodiments.

FIG. 22 is a flowchart of a DUT-side training operation of the test system of FIG. 21 according to some example embodiments.

FIG. 23 is a diagram illustrating an open test operation of a test system according to some example embodiments.

FIGS. 24 and 25 are diagrams illustrating signal level adjustment operations of a test system according to some example embodiments.

### DETAILED DESCRIPTION

Hereinafter, some example embodiments will be described with reference to the accompanying drawings.

The following terms such as, for example, “at least one of A, B, and C” and similar language (e.g., “at least one selected from the group consisting of A, B, and C”) when used in the specification may be construed as A only, B only, C only, or any combination of two or more of A, B, and C, such as, for instance, ABC, AB, BC, and AC.

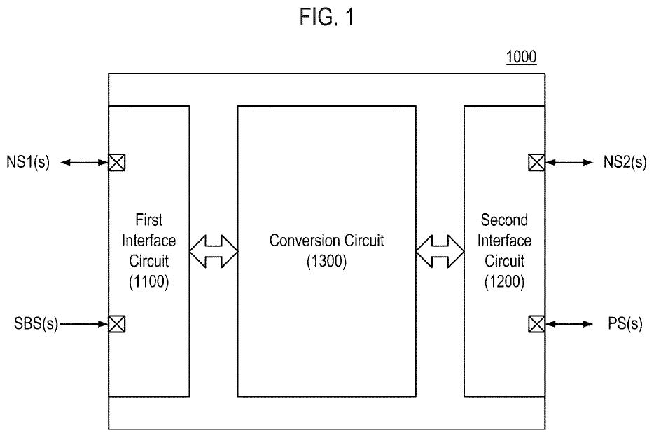

FIG. 1 is a block diagram of an interface chip according to some example embodiments.

Referring to FIG. 1, an interface chip 1000 according to some example embodiments may include a first interface circuit 1100, a second interface circuit 1200, and a conversion circuit 1300. The interface chip 1000 according to some example embodiments may be implemented as a semiconductor chip such as for example a field programmable gate array (FPGA), an application specific integrated circuit (ASIC), or an application processor (AP).

The first interface circuit 1100 may be connected to a test device and configured to provide an interface for a first non-return to zero (NRZ) signal and a sideband signal SBS(s) to the test device. For example, the first interface circuit 1100 may be configured to provide an interface for signals that may be transmitted or received between the test device and the interface chip 1000.

In the present application, a test device may be defined as a device providing a testing function for a device under test (DUT) connected to the second interface circuit 1200. The test device may apply various signals to the DUT through the interface chip 1000 to test the DUT, and examples of the applied signals may include a first NRZ signal NS1(s) and a sideband signal SBS(s).

The first NRZ signal NS1(s) is an NRZ-modulated signal, and thus may have two signal levels. In the present application, the “first NRZ signal” may refer to signals modulated using NRZ and transmitted or received between the test device and the interface chip 1000. Similarly, the “second NRZ signal” may refer to signals modulated using NRZ and transmitted or received between the DUT and the interface chip 1000.

The sideband signal SBS(s) may be defined as a signal applied from the test device to the interface chip 1000 to control or operate the interface chip 1000. The sideband signal SBS(s) may be applied only to the interface chip 1000 and distinguished from other signals that may be converted in any manner through the conversion circuit 1300 and applied from the test device to the DUT and vice versa. In the present application, all signals defined to have the above-mentioned purpose (signals applied only to the interface chip 1000 to control or operate the interface chip 1000) may be classified as sideband signals SBS(s).

According to some example embodiments, the first interface circuit 1100 may include a plurality of pins to transmit or receive signals to or from the test device. In FIG. 1, for brevity of the drawing, only one pin is illustrated for each of the first NRZ signal NS1(s) and the sideband signal SBS(s), but a plurality of pins may be provided depending on the number of corresponding first NRZ signals NS1(s) or sideband signals SBS(s).

The first interface circuit 1100 may include analog elements, such as drivers to transmit or receive signals to or from the test device in addition to the plurality of pins.

The second interface circuit 1200 may be connected to the DUT and configured to provide an interface for a second NRZ signal NS2(s) and a pulse amplitude modulation (PAM) signal to the DUT. For example, the second interface circuit 1200 may be configured to provide an interface for signals that may be transmitted or received between the DUT and the interface chip 1000.

In the present application, the DUT may be defined as a target device tested by a test device.

A PAM signal PS(s) may be a PAM-X modulated signal, where X is a positive integer greater than or equal to 3. For example, when X=3, the PAM signal PS(s) may be a PAM-3 modulated signal. The PAM-X modulated signal may have X signal levels.

According to some example embodiments, the second interface circuit 1200 may include a plurality of pins to transmit or receive signals to or from the DUT. In FIG. 1, for brevity of the drawing, only one pin is illustrated for each of the second NRZ signal NS2(s) and the PAM signal PS(s), but a plurality of pins may be provided depending on the number of corresponding second NRZ signals NS2(s) or PAM signals PS(s).

According to some example embodiments, each pin provided in the second interface circuit 1200 may be configured to transmit or receive an NRZ signal and/or a PAM signal depending on the register setting of the conversion circuit. For example, a pin configured to transmit or receive the second NRZ signal NS2(s) of FIG. 1 may be configured to transmit or receive the PAM signal PS(s) or both the second NRZ signal NS2(s) and the PAM signal PS(s) depending on the register setting. Similarly, a pin configured to transmit or receive the PAM signal of FIG. 1 may be configured to transmit or receive the second NRZ signal NS2(s) or both the second NRZ signal NS2(s) and the PAM signal PS(s) depending on the register setting.

For example, the pins illustrated in FIG. 1 are merely configured to correspond to each signal for ease of description. According to the above-described embodiments, each pin may transmit or receive an NRZ signal and/or a PAM signal depending on the register setting.

The second interface circuit 1200 may include one or more analog elements, such as a driver for transmitting or receiving signals to or from the test device, and/or elements for applying a delay for synchronization (for example, a flip-flop, a multiplexer, or the like) in addition to the plurality of pins.

The test device may apply various signals to the DUT through the interface chip 1000 to test the DUT, and examples of the applied signals may include the first NRZ signal NS1(s) and the sideband signal SBS(s).

The conversion circuit 1300 may be connected to the first interface circuit 1100 and the second interface circuit 1200 and configured to provide conversion operations for various signals transmitted or received between the test device and the DUT. In the present application, the “conversion operation” provided by the conversion circuit 1300 may include data rate adjustment of a data rate of a signal and/or signal modulation.

According to some example embodiments, the conversion circuit 1300 may be configured to provide conversion between the first NRZ signal NS1(s) and the second NRZ signal NS2(s) or between the first NRZ signal NS1(s) and the PAM signal PS(s) based on the sideband signal SBS(s). For example, the conversion circuit 1300 may be configured to provide bidirectional conversion between the test device and the DUT. The sideband signal SBS(s) may be used for conversion, and the sideband signal used for conversion between NRZ signals may be defined separately from the sideband signal used between the NRZ signal and the PAM signal PS(s).

According to some example embodiments, the conversion circuit 1300 may up-convert a data rate of the first NRZ signal NS1(s) based on the sideband signal SBS(s) and provide the converted NRZ signal as the second NRZ signal NS2(s). Alternatively, the conversion circuit 1300 may down-convert a data rate of the second NRZ signal NS2(s) based on the sideband signal SBS(s) and provide the converted NRZ signal as the first NRZ signal NS1(s). Alternatively, the conversion circuit 1300 may provide conversion for a modulation scheme between the first NRZ signal NS1(s) and the PAM signal PS(s).

According to some example embodiments, the test device may be configured to support or require a data rate, relatively lower than the data rate supported or required by the DUT, or to support or require a modulation scheme different from that of the DUT. Therefore, the conversion circuit 1300 may be provided between the test device and the DUT to convert signals into the speed and/or modulation scheme required by each side, enabling a bidirectional interface between the test device and the DUT.

According to the above-described embodiments, the interface chip 1000 may provide a bidirectional interface between a test device and a DUT supporting or requiring different data rates and/or modulation schemes, enabling the DUT to be tested even with a test device of a different standard.

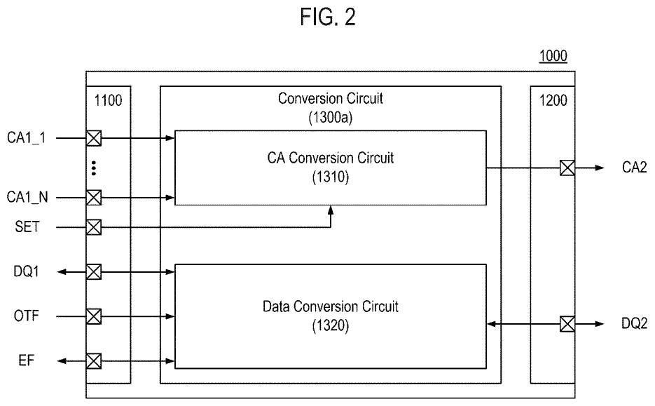

FIG. 2 is a diagram illustrating an interface chip according to some example embodiments.

Referring to FIG. 2, a first interface circuit 1100 according to some example embodiments may be configured to receive a plurality of first CA (command address) signals CA1_1 to CA1_N classified as first NRZ signals and transmit or receive a first data signal DQ1 and an error flag signal EF classified as first NRZ signals. The first interface circuit 1100 may be configured to receive a setting signal SET and an on-the-fly (OTF) signal classified as sideband signals. The first interface circuit 1100 may include a plurality of pins for transmitting or receiving the above-mentioned signals.

Each first CA signal may be considered a signal transmitted through a single CA channel from the test device. The CA pins on a test device side may be classified into two CA channels. For example, there may be a CA channel mapped to CA pins including even-numbered CA pins and a CA channel mapped to CA pins having odd-numbered CA pins.

Although only one first data signal DQ1 is illustrated in FIG. 2, in some example embodiments a plurality of first data signals DQ1 may be transmitted or received through a plurality of channels, similarly to the first CA signal. For example, a channel through which the data signal is transmitted or received may correspond to a most significant bit (MSB) or a least significant bit (LSB).

Each channel for transmitting or receiving each signal may transmit or receive a signal of the number of bits, corresponding to the number of pins included in the channel.

The second interface circuit 1200 may be configured to transmit a second CA signal CA2 classified as a second NRZ signal. The second interface circuit 1200 may be configured to transmit or receive a second data signal DQ2 classified as a PAM signal. The second interface may include a plurality of pins for transmitting or receiving the above-mentioned signals.

According to some example embodiments, the first interface circuit 1100 and the second interface circuit 1200 may transmit or receive a CA signal through a CA pin, transmit or receive a data signal through a DQ pin, and transmit or receive an error flag signal EF through a DQE pin.

The conversion circuit 1300 may include a CA conversion circuit 1310 and a data conversion circuit 1320 connected to the first interface circuit 1100 and the second interface circuit 1200.

The CA conversion circuit 1310 may perform a conversion operation on the CA signal and an internal setting operation for the conversion operation. A setting signal SET classified as a sideband signal may be applied to the CA conversion circuit 1310 from the test device to perform the setting operation. The setting signal SET may be a signal for setting or determining whether to output the second CA signal CA2 through the second interface circuit 1200.

When the test device intends to provide a CA signal to the DUT to perform a test, the test device may provide a setting signal SET having a first logic value (for example, logic low or logic high) to the interface chip 1000. Alternatively, when the test device intends to set the interface chip 1000, the test device may provide a setting signal SET having a second logic value (for example, logic high or logic low) to the interface chip 1000.

When a setting signal SET having a second logic value is provided to the interface chip 1000, the interface chip 1000 does not output the second CA signal CA2. The CA conversion circuit 1310 may perform the setting operation based on a register setting value. An example of the setting operation according to some example embodiments may include a mode setting operation for setting how to provide the second CA signal CA2. In the mode setting operation, when the test device cannot provide a CA signal to the DUT at a data rate supported by the test device (for example, when it is difficult to satisfy the data rate required by the DUT), the CA conversion circuit 1310 may operate to output the second CA signal CA2 using the plurality of first CA signals CA1_1 to CA1_N.

Alternatively, in the mode setting operation, when the test device may provide a CA signal to the DUT at a data rate required by the DUT (for example, when the data rate required by the DUT may be satisfied), the CA conversion circuit 1310 may operate to output the second CA signal CA2 using at least a portion of the plurality of first CA signals CA1_1 to CA1_N. The at least a portion of the first CA signals may be transmitted through at least a portion of the plurality of CA channels through which the plurality of first CA signals CA1_1 to CA1_N are transmitted from the test device.

When the plurality of first CA signals CA1_1 to CA1_N are used, the CA conversion circuit 1310 may up-convert the data rate of the CA signal to be provided from the test device to the DUT. For example, the second CA signal CA2 may have a higher speed than the data rate of the first CA signal.

When at least a portion of the plurality of first CA signals CA1_1 to CA1_N are used, the CA conversion circuit 1310 may maintain the data rate of the CA signal as it is. For example, the second CA signal CA2 may have the same speed as the data rate of the first CA signal.

In some example embodiments, the test device may support for example a speed of 8 Gbps and a data rate of each first CA signal is 5 Gbps. When the speed required by the memory device is higher than 8 Gbps, the CA conversion circuit 1310 may perform a conversion operation using the plurality of first CA signals CA1_1 to CA1_N through the mode setting operation. Alternatively, when the speed required by the memory device is 8 Gbps or less, the CA conversion circuit 1310 may perform a conversion operation using at least a portion of the first CA signals through the mode setting operation.

According to some example embodiments, the data conversion circuit 1320 may perform a conversion operation on a data signal based on an OTF signal OTF classified as a sideband signal. The OTF signal OTF may be applied from the test device, and may be used to convert the data signal.

In some example embodiments, the data conversion circuit 1320 may receive the first data signal DQ1 from the test device, and may convert the first data signal DQ1 into the second data signal DQ2 and output the second data signal DQ2 to the DUT. For example, the data conversion circuit 1320 may expand the first data signal DQ1 based on the OTF signal OTF. A data signal for encoding the number of symbols required by the DUT may be prepared through the expansion of the first data signal DQ1.

The data conversion circuit 1320 may generate a cyclic redundancy check (CRC) for the first data signal DQ1 and provide the second data signal DQ2 to the second interface circuit 1200 based on encoding the expanded first data signal E_DQ1, the error flag signal EF, and the CRC. Encoding refers to the conversion of a bit-wise signal into a symbol-wise signal, and the NRZ signal may be modulated into a PAM signal through encoding. Encoding may be performed through an encoding scheme defined for each signal.

In some example embodiments, the data conversion circuit 1320 may receive the second data signal DQ2 from the DUT, and may convert the second data signal DQ2 into the first data signal DQ1 and output the first data signal DQ1 to the test device. For example, the data conversion circuit 1320 may decode the second data signal DQ2 and select specific bits from some decoded signals based on the OTF signal OTF. Through this selection, only the number of bits of data signal required by the test device may be provided to the test device.

The data conversion circuit 1320 may generate a pass/fail (PF) signal through CRC comparison of some decoded signals. The data conversion circuit 1320 may output the PF signal to the test device through the first interface circuit 1100.

The data conversion circuit 1320 may output some decoded signals corresponding to an error flag to the test device through the first interface circuit 1100.

Decoding refers to the conversion of a symbol-wise signal into a bit-wise signal. Through this decoding, the PAM signal may be modulated into an NRZ signal. Decoding may be performed through a decoding scheme defined for each signal.

According to the above-described some example embodiments, the interface chip 1000 may convert a signal from the test device in response to a data rate or a modulation scheme required by the DUT, or may convert a signal from the DUT in response to a data rate or a modulation scheme required by the test device. As a result, interface constraints for testing may be addressed and/or mitigated, and/or utilization of existing equipment may be increased and/or investment in new equipment may be reduced.

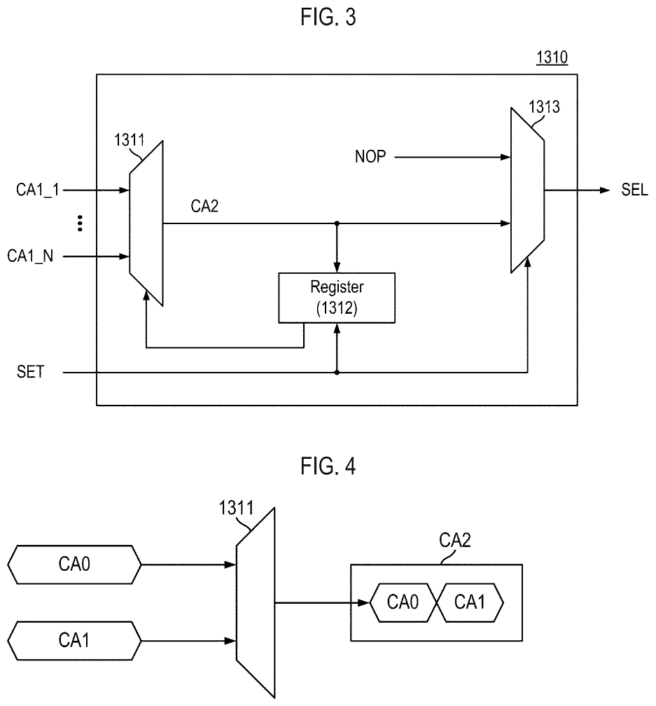

FIG. 3 is a diagram illustrating a CA conversion circuit of FIG. 2 according to some example embodiments.

Referring to FIG. 3, the CA conversion circuit 1310 according to some example embodiments may include a demultiplexer 1311, a register 1312, and a multiplexer 1313.

The demultiplexer 1311 may be configured to demultiplex a plurality of first CA signals CA1_1 to CA1_N based on a setting signal SET classified as a sideband signal, and provide a second CA signal CA2 classified as a second NRZ signal to the second interface circuit 1200 in response to the demultiplexing. The demultiplexer 1311 may perform demultiplexing based on the demultiplexing setting.

According to some example embodiments, through demultiplexing, the plurality of first CA signals CA1_1 to CA1_N are converted into a continuous signal (for example, serialized). Accordingly, the second CA signal CA2 output by the demultiplexing may have a higher speed than the first CA signal. The demultiplexer 1311 performs serialization, and thus may also be referred to as a serializer.

As an example, in some example embodiments the plurality of first CA signals CA1_1 to CA1_N includes two first signals.

The demultiplexer 1311 may demultiplex the first CA signals, received from two CA channels, to output a single second CA signal CA2. For example, the demultiplexer 1311 may be implemented as a 2:1 structure performing demultiplexing on two input channels and one output channel. The output second CA signal CA2 may have a data rate higher than the data rate of the first CA signal. For example, when the data rate of the first CA signal is k (where k is a real number greater than 0), the data rate of the second CA signal CA2 may be twice as much, or 2k.

According to some example embodiments, the demultiplexer 1311 may be implemented to perform demultiplexing greater than 2:1, for example, N:1 (where N is a positive integer, and is the number of CA channels and the number of the plurality of first CA signals CA1_1 to CA1_N).

The demultiplexer 1311 may output the second CA signal CA2 to the register 1312 and the multiplexer 1313.

The register 1312 may perform various settings for the operation of the interface chip. The second CA signal CA2 may be applied to the register 1312 for setting, or the register 1312 may enter setting mode based on power-up and initialization and/or configuration of an interface chip, or the setting of the register 1312 may be performed. The CA signal applied to the register 1312 may include a command and address for setting the register 1312.

According to some example embodiments, the register 1312 may perform the above-mentioned mode setting operation based on the setting signal SET indicating a second logic value. The register 1312 may set the demultiplexing through the mode setting operation.

For example, the register 1312 may set the demultiplexing performed by the demultiplexer 1311 to 1:1 mode based on a data rate required for the second CA signal CA2 being less than K (where K is a real number). Alternatively, the register 1312 may set the demultiplexing performed by the demultiplexer 1311 to N: 1 mode based on the data rate being greater than or equal to K. For example, the register 1312 may set whether to operate the demultiplexing in 1:1 mode or N: 1 mode in consideration of the data rate required by the DUT. When the test device determines that a single CA channel is unable to support the data rate required by the DUT, the register 1312 may set the demultiplexing to N: 1 mode.

The multiplexer 1313 may be configured to select one of the second CA signal CA2 corresponding to the demultiplexing and a no-operation (NOP) signal and output the selected signal.

According to some example embodiments, the multiplexer 1313 may receive the setting signal SET as a signal for selection, select an NOP signal NOP indicating that the DUT operates in an idle state, based on the setting signal SET indicating a second logic value, and provide the NOP signal NOP to the second interface circuit 1200.

Alternatively, the multiplexer 1313 according to some example embodiments may select the second CA signal CA2 based on the setting signal SET indicating a first logic value, and provide the second CA signal CA2 to the second interface circuit 1200.

According to the above-described embodiments, although the register 1312 has been described as being included in the CA conversion circuit 1310, the register 1312 may be separately provided in other components within the conversion circuit 1300, or in the conversion circuit 1300, the first interface circuit 1100, and/or the second interface circuit 1200, rather than in the CA conversion circuit 1310.

The register 1312 according to some example embodiments may perform various settings for the interface chip in addition to the above-mentioned mode setting for demultiplexing. For example, the register 1312 may set the first interface circuit 1100 and/or the second interface circuit 1200, or may set a training operation to be described later, latency and delay related to an interface chip, and various analog elements included in the interface chip.

The register 1312 may generate a register signal to control and/or set operations of the elements related to the interface chip.

According to the some example embodiments, the CA conversion circuit 1310 may provide a CA signal having an increased speed to the DUT through demultiplexing for a plurality of CA channels. The CA signal may be modulated using NRZ modulation, which is commonly applied with the test device and the DUT. For example, conversion of the modulation scheme for the CA signal may not be required. The CA conversion circuit 1310 may flexibly set the demultiplexing in consideration of the data rate required by the DUT.

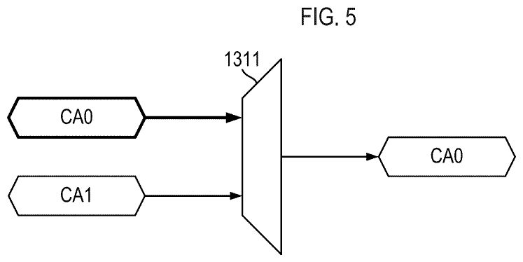

FIG. 4 is a diagram illustrating a CA conversion operation in 2:1 mode according to some example embodiments, and FIG. 5 is a diagram illustrating a CA conversion operation in 1:1 mode according to some example embodiments. In FIGS. 4 and 5, the CA conversion operation may be regarded as an operation of the demultiplexer when the above-mentioned setting signal SET indicates a first logic value.

Referring to FIG. 4, when demultiplexing is set to 2:1 mode, the demultiplexer 1311 may perform demultiplexing of two first CA signals CA0 and CA1 received from two CA channels. The second CA signal CA2, output as a result of the demultiplexing, may be a signal obtained by serializing the two first CA signals CA0 and CA1. Therefore, the second CA signal CA2 may have a speed twice that of the first CA signal.

Referring to FIG. 5, when demultiplexing is set to 1:1 mode, the demultiplexer 1311 may select one of the two first CA signals CA0 and CA1 received from two CA channels (for example, CA0) and output the selected CA signal as it is. For example, the second CA signal CA2 is the same as one first CA signal. A single first CA signal to be selected may be CA1 as well as CA0, as illustrated. When the speeds of the first CA signals are all the same, any first CA signal may be selected in the 1:1 mode to satisfy the speed required by the DUT.

For example, the two first CA signals CA0 and CA1 may be mapped to even-numbered CA pins and odd-numbered CA pins, respectively.

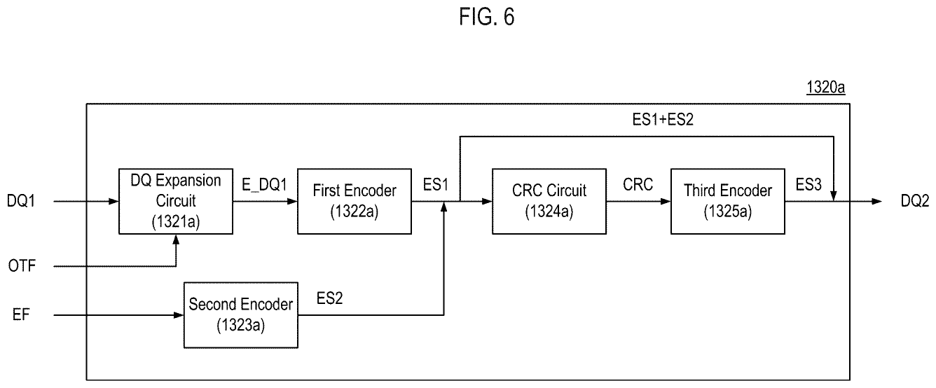

FIG. 6 is a diagram illustrating a data conversion circuit according to some example embodiments.

Referring to FIG. 6, a data conversion circuit 1320a according to some example embodiments may include a DQ expansion circuit 1321a, a first encoder 1322a, a second encoder 1323a, a CRC circuit 1324a, and a third encoder 1325a. The data conversion circuit 1320a of FIG. 6 may be configured for an operation in a DUT direction in the test device (for example, testing during a data write operation).

The DQ expansion circuit 1321a may be configured to receive the first data signal DQ1, which is an NRZ signal, and the OTF signal OTF from the test device, and to expand the first data signal DQ1 based on the OTF signal OTF. For example, the DQ expansion circuit 1321a may expand the number of bits of the first data signal DQ1 by copying the first data signal DQ1 based on the OTF signal OTF or inverting a logic of the first data signal based on the OTF signal. The DQ expansion circuit 1321a may apply copying and/or inversion to specific bits of the first data signal DQ1, or may apply copying or inversion to all bits. The DQ expansion circuit 1321a may perform expansion through various operations to increase the number of bits of the signal in addition to the copying or inversion.

The DQ expansion circuit 1321a may expand the number of bits by the amount required to compensate for the number of bits needed for encoding by the first encoder 1322a, and output the expanded first data signal E_DQ1.

The first encoder 1322a may encode the expanded first data signal E_DQ1 to output a first encoded signal ES1.

The second encoder 1323a may receive an error flag signal EF from the test device and encode the error flag signal EF to output a second encoded signal ES2. For example, the error flag signal EF may be a poison/severity (P/S) signal supported by double data rate (DDR). The error flag signal EF may consist of 2 bits and may indicate whether an error has occurred in a memory device and severity of the error.

The first encoded signal ES1 and the second encoded signal ES2 may be provided together to the CRC circuit 1324a. The CRC circuit 1324a may generate a CRC from the first encoded signal ES1.

The third encoder 1325a may encode the CRC to output a third encoded signal ES3.

Ultimately, the second data signal DQ2 output through the data conversion circuit 1320a may include the first encoded signal to the third encoded signal ES1 to ES3.

Each of the first encoder to the third encoder 1322a to 1325a may encode pre-defined bits in an encoding-target signal into a pre-defined number of symbols. The pre-defined number of bits and the pre-defined number of symbols may be set to be the same or different for each encoder. The encoding-target signal may be encoded in units of symbols, and thus converted from an NRZ signal to a PAM signal. Accordingly, the first encoded signal to the third encoded signal ES1 to ES3 may be signals in units of symbols.

Some example embodiments based on a data rate required by the memory device are provided. In some example embodiments graphic DDR (GDDR) that is a graphic-oriented DDR, GDDR7 may be cited as an example of the Joint Electron Device Engineering Council (JEDEC) standard. GDDR7 may require a data rate of 32 Gbps or higher.

In some example embodiments in which the data is less than 32 Gbps, the test device may transmit and receive 128 bits during 8 unit intervals (UI). The test device may transmit 32 bits of the OTF signal OTF from two channels through an OTF pin, and may transmit and receive 2 bits of the error flag signal EF through a DQE pin.

The DQ expansion circuit 1321a may expand 128 bits of first data signal DQ1 to 256 bits. The OTF signal OTF used for expansion may be 32 bits. A size of the OTF signal OTF may be set to be different depending on the number of bits that need to be expanded. The first encoder 1322a may output 163 symbols of first encoded signal ES1 through 11b7s encoding. Hereinafter, ‘xbys’ in the present application may be defined as representing an encoding method of mapping x bits to y symbols.

The second encoder 1323a may output one symbol of second encoded signal ES2 through 2b1s encoding. The CRC circuit 1324a may generate 18 bits of CRC from the first encoded signal ES1, and the third encoder 1325a may output 12 symbols of third encoded signal ES3 through 3b2s encoding. Ultimately, the data conversion circuit 1320a may output 176 symbols of second data signal DQ2 including the 163 symbols of first encoded signal ES1, the one symbol of second encoded signal ES2, and the 12 symbols of third encoded signal ES3. The second data signal DQ2 may be modulated from NRZ to PAM through the above-mentioned encoding.

In some example embodiments in which the data is 32 Gbps or higher, the test device may transmit and receive 64 bits during 4 UI. The test device receives 48 bits of the OTF signal OTF from 6 channels through the OTF pin.

The DQ expansion circuit 1321a may expand the 64 bits of first data signal DQ1 to 256 bits. The OTF signal OTF used for expansion may be 48 bits. A size of the OTF signal OTF may be set to be different depending on the number of bits that need to be expanded. The first encoder 1322a may output 163 symbols of first encoded signal ES1 through 11b7s encoding. Then, similarly to the some example embodiments in which the data rate is less than 32 Gbps, the first encoder to the third encoder 1322a to 1325a may perform encoding, and the CRC circuit 1324a may generate a CRC. Accordingly, the data conversion circuit 1320a may output 176 symbols of second data signal DQ2.

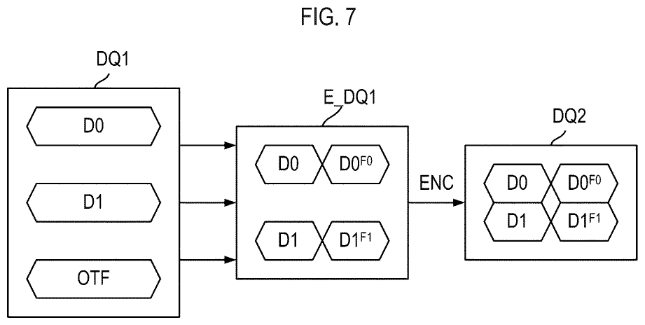

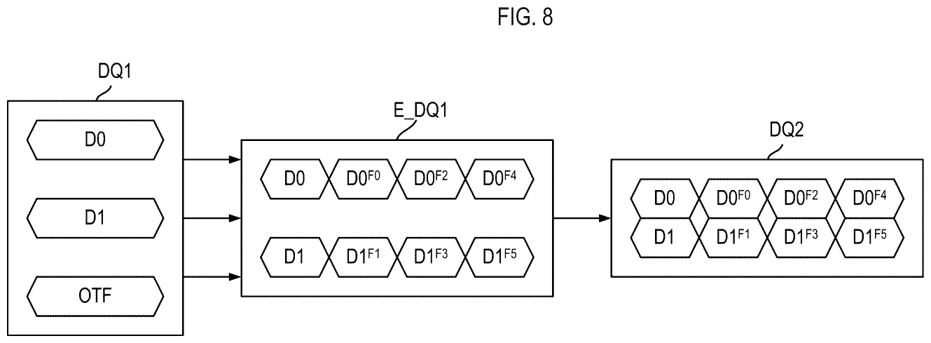

FIGS. 7 and 8 are diagrams illustrating conversion operations of a data conversion circuit according to Example scenarios. In FIG. 7, some example embodiments in which a data rate is less than 32G bps in GDDR7 is provided. In FIG. 8, some example embodiments in which a data rate is 32 Gbps or higher in GDDR7 is provided.

Referring to FIG. 7, the first data signal DQ1 may be expanded to the first data signal E_DQ1 expanded based on the OTF signal OTF, through the data conversion circuit 1320 according to the above-described embodiments. The expanded first data signal E_DQ1 may include original first data signals D0 and D1 and a first data signal DQ1 copied (and/or inverted) based on OTF signals F0 and F1 corresponding to two channels (or pins) D0^{F0} and D1^{F1}.

The expanded first data signal E_DQ1 may be encoded into a second data signal DQ2, a PAM signal, through encoding ENC. The second data signal DQ2 may be a PAM3-modulated signal and have three voltage levels.

Referring to FIG. 8, the expanded first data signal E_DQ1 expanded through the data conversion circuit 1320 according to the above-described embodiments may include the original first data signals D0 and D1 and the first data signal DQ1 copied (and/or inverted) based on OTF signals F0 to F5 corresponding to six channels (or pins) D0^{F0}, D0^{F2}, D0^{F4}, D1^{F1}, D1^{F3}, and D1^{F5}. In the scenarios in which the data rate is 32 Gbps or higher, the number of bits of the first data signal DQ1 received from the test device is 64 bits, so that more OTF signals OTF and expansion are required.

According to the above-described embodiments, the data conversion circuit 1320 may provide compatibility for an operation of writing a data signal between a test device and a memory device having different modulation schemes NRZ/PAM, different data rates, and/or different numbers of pins.

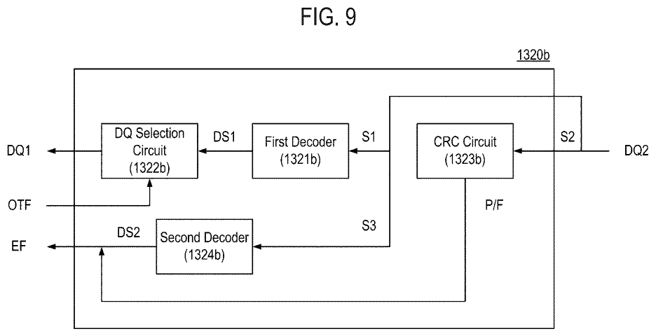

FIG. 9 is a diagram illustrating a data conversion circuit according to some example embodiments.

Referring to FIG. 9, a data conversion circuit 1320b according to some example embodiments may include a first decoder 1321b, a DQ selection circuit 1322b, a CRC circuit 1323b, and a second decoder 1324b. The data conversion circuit of FIG. 9 may be configured for operation from the DUT towards the test device (for example, testing during a data read operation).

The first decoder 1321b may decode a plurality of first symbols S1 from the second data signal DQ2, which is a PAM signal and is in units of symbol, to obtain a first decoded signal DS1. The plurality of first symbols S1 may be first symbols excluding a plurality of second symbols S2 and third symbols S3, which are symbols associated with errors, from the second data signal DQ2. The first decoder 1321b may output the first decoded signal DS1 to the DQ selection circuit 1322b.

The DQ selection circuit 1322b may select specific bits from the first decoded signal DS1 based on an OTF signal OTF and output the specific bits as the first data signal DQ1. Contrary to the test operations in the data write operation, it may be difficult for the specification of the data read from the DUT to be compatible with the specification required by the test device. For example, it may be difficult to receive read data using the DQ pins provided in the test device. Therefore, the DQ selection circuit 1322b may select only specific bits from the first decoded signal DS1 in consideration of the number of DQ pins. The number of selected bits may vary depending on the number of DQ pins.

The DQ selection circuit 1322b may repeatedly output the selected specific bits, so that the first decoded signal DS1 may be completely output even when the number of DQ pins of the test device is difficult to be compatible.

The CRC circuit 1323b may generate a PF signal P/F through a CRC comparison of a plurality of second symbols S2 and output the PF signal P/F. The PF signal P/F indicates whether there is an error in data in CRC verification. When the PF signal P/F indicates pass, it is verified that there is no error in the received signal, whereas when the PF signal P/F indicates failure, there is an error in the received signal.

The second decoder 1324b may decode the third symbol S3 corresponding to the error flag from the second data signal DQ2 to obtain a second decoded signal DS2 and output the obtained second decoded signal DS2.

Ultimately, the data conversion circuit 1320b may output a signal including the PF signal P/F output from the CRC circuit 1323b and the second decoded signal DS2 output from the second decoder 1324b as an error flag signal EF.

As described above, the first to second decoders 1321b and 1324b may decode pre-defined symbols from a decoding-target signal into a pre-defined number of bits. The pre-defined number of symbols and the pre-defined number of bits may be set to be the same or different for each decoder. As encoding is performed in units of bits, the decoding target signal may be converted from a PAM signal to an NRZ signal. Accordingly, the first decoded signal and the second decoded signal DS1 and DS2 may be signals in units of symbols.

As described above, some example embodiments based on a data rate of 32 Gbps may be taken into consideration.

In some example embodiments in which the data rate is less than 32 Gbps, the data conversion circuit 1320b may be provided with 176 symbols of second data signal DQ2. The first decoder 1321b may decode 163 symbols, among the 176 symbols, using 7s11b decoding and output 256 bits of first decoded signal DS1. In the present application, ‘xsyb’ is defined as representing a decoding method of mapping x number of symbols to y number of bits.

The CRC circuit 1323b may perform a CRC comparison based on 12 symbols, among the 176 symbols, and may output 1 bit of PF signal P/F based on a result of the comparison. The second decoder 1324b may decode the remaining 1 symbol, among the 176 symbols, through 1s2b decoding and outputs 2 bits of second decoded signal DS2.

The DQ selection circuit 1322b may select 128 bits from the 256 bits of the first decoded signal DS1 based on an OTF signal OTF. The OTF signal OTF used for selection may be 32 bits of signal. The DQ selection circuit 1322b may output 128 bits twice. The test device may read the 128 bits of data twice.

Ultimately, the data conversion circuit 1320b may output 128 bits of first data signal DQ1, 2 bits of error flag signal EF, and 1 bit of PF signal P/F. The first data signal DQ1 may be converted from PAM to NRZ modulation through the above-described decoding.

In some example embodiments in which the data rate is 32 Gbps or higher, the DQ selection circuit 1322b may select 64 bits from 256 bits of first decoded signal DS1 based on the OTF signal OTF. The OTF signal OTF used for selection may be 48 bits of signal. Therefore, the data conversion circuit 1320b may output 64 bits of first data signal DQ1. The data conversion circuit 1320b may output 64 bits four times. The test device may read 64 bits of data four times.

According to the above-described embodiments, the data conversion circuit 1320b may provide compatibility for data signal read operations between test devices and memory devices having different modulation schemes NRZ/PAM, different data rates, and/or different number of pins.

According to some example embodiments, each component of the data conversion circuits 1320b of FIGS. 6 and 9 may be configured or implemented to perform both conversion operations based on a write operation and a read operation. For example, the DQ expansion circuit 1321a and the DQ selection circuit 1322b may be configured in an integrated manner, the first encoder 1322a and the first decoder 1321b may be integrally configured, and the third encoder 1325a and the second decoder 1324b may be integrally configured. The CRC circuit 1323b may be configured to perform both CRC generation and CRC comparison.

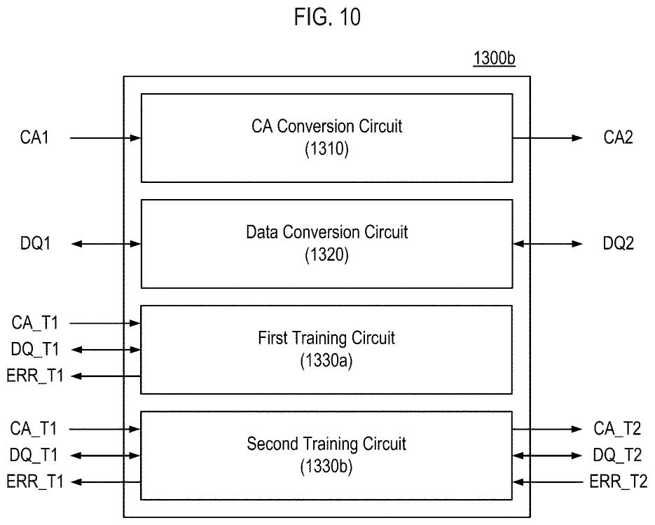

FIG. 10 is a block diagram of a conversion circuit according to some example embodiments.

Referring to FIG. 10, a conversion circuit 1300b according to some example embodiments may further include a first training circuit 1330a and a second training circuit 1330b in addition to the CA conversion circuit 1310 and the data conversion circuit 1320 according to the above-described embodiments (for example, FIGS. 2 to 9).

The first training circuit 1330a and the second training circuit 1330b according to some example embodiments may be configured separately from the CA conversion circuit 1310 and the data conversion circuit 1320. According to the above-described embodiments, the CA conversion circuit 1310 may convert a first CA signal CA1, a unidirectional signal, into a second CA signal CA2. The data conversion circuit 1320 may convert between a first DQ signal and second DQ signal, bidirectional signals.

The first training circuit 1330a may be configured for training on the test device side.

The first training circuit 1330a may receive a first CA training signal CA_T1, defined as a training signal for CA, from the test device and perform training on the CA signal based on the received signal. The first training circuit 1330a may perform training on the data signal while transmitting or receiving a first data training signal DQ_T1, defined as a training signal for data, to or from the test device. The first training circuit 1330a may perform training on the error detection signal by generating a first error training signal ERR_T1 defined as a training signal for error detection and providing the first error training signal ERR_T1 to the test device.

In the present application, training may be defined as an operation to synchronize (or match the skew of) at least two signals, and may be performed before a normal operation is performed by the test device according to the above-described embodiments.

The second training circuit 1330b may be configured for training on the DUT side.

The second training circuit 1330b may be configured to convert the first CA training signal CA_T1 into a second CA training signal CA_T2 and to convert between the first data training signal DQ_T1 and the second data training signal DQ_T2. The second training circuit 1330b may be configured to receive a second error training signal ERR_T2, defined as a training signal for error detection, from the DUT and to convert the second error training signal ERR_T2 into a first error training signal ERR_T1.

The first CA training signal CA_T1 and the second CA training signal CA_T2 may be transmitted or received on the same CA pin on which the first CA signal CA1 and the second CA signal CA2 are transmitted or received. The first data training signal DQ_T1 and the second data training signal DQ_T2 may be transmitted or received on the same DQ pin on which the first data signal DQ1 and the second data signal DQ2 are transmitted or received. The first error training signal ERR_T1 and the second error training signal ERR_T2 may be transmitted or received on the same pin on which the error detection signal is transmitted or received.

According to the above-described embodiments, the conversion circuit 1300b may include a first training circuit 1330a and a second training circuit 1330b, which are used for training to synchronize signals, separate from the circuits 1310 and 1320 used for normal operations, such as the conversion of CA signals and data signals for testing. The training circuits may perform synchronization through hardware distinct from the normal operation. Training may require operations that involve load, such as random data generation. However, when the first training circuit 1330a and the second training circuit 1330b are provides separately, both the normal operation and the training may be efficiently performed.

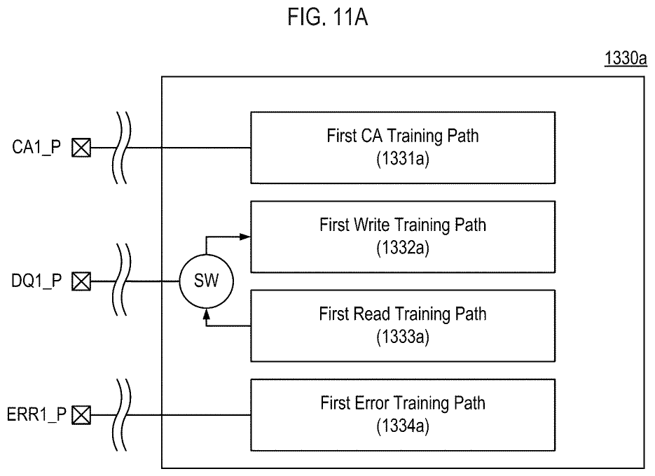

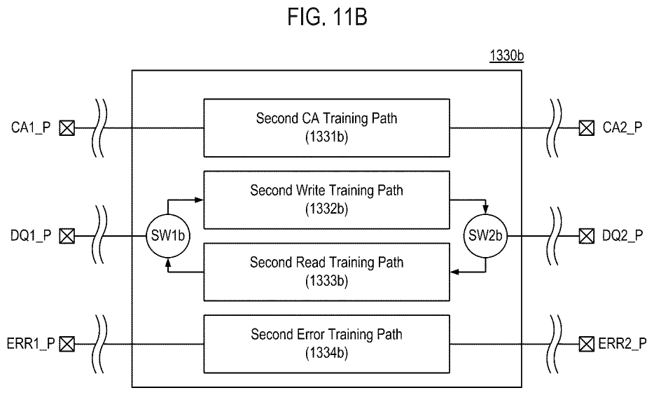

FIG. 11A is a diagram illustrating a first training circuit according to some example embodiments.

Referring to FIG. 11A, a first training circuit 1330a according to some example embodiments may include a first CA training path 1331a for CA training, a first write training path 1332a for write training, a first read training path 1333a for read training, and a first error training path 1334a.

Each training path may be connected to one or more pins corresponding to a training signal, among pins included in the first interface circuit 1100 and the second interface circuit 1200 according to some example embodiments. For example, the first CA training path 1331a may be connected to one or more first CA pins CA1_P, and the first write training path 1332a and the first read training path 1333a may be connected to one or more first DQ pins DQ1_P. The first error training path 1334a may be connected to one or more first error pins ERR1_P.

The first CA training path 1331a may be configured to perform training on the test device based on the CA training signal provided from the test device.

The first write training path 1332a and the first read training path 1333a may be connected to a switch SW. Pins to be respectively connected to training paths may be mapped through the switch SW.

The switch SW may be connected to one or more first DQ pins DQ1_P to provide a write training signal, provided from the one or more first DQ pins DQ1_P, to the first write training path 1332a or to provide a read training signal, provided from the first read training path 1333a, to the one or more first DQ pins DQ1_P.

The first write training path 1332a may receive a write training signal from the one or more first DQ pins DQ1_P according to the switching of the switch SW and perform write training, and the first read training path 1333a may transmit a read training signal to the one or more first DQ pins DQ1_P according to the switching of the switch SW and perform read training.

The first error training path 1334a may generate a first error training signal and provide the first error training signal to the first interface circuit through one or more first error pins ERR1_P.

FIG. 11B is a diagram illustrating a second training circuit according to some example embodiments.

Referring to FIG. 11B, the second training circuit 1330b according to some example embodiments may include a second CA training path 1331b for CA training, a second write training path 1332b for write training, a second read training path 1333b for read training, and a second error training path 1334b.

Each training path may be connected to one or more pins corresponding to a training signal, among pins included in the first interface circuit 1100 and the second interface circuit 1200 according to the some example embodiments. For example, the second CA training path 1331b may be connected to one or more first CA pins CA1_P and one or more second CA pins CA2_P, and the second write training path 1332b and the second read training path 1333b may be connected to one or more first DQ pins DQ1_P and one or more second DQ pins DQ2_P.

The second CA training path 1331b may be a path for providing a training signal for CA, provided from one or more first CA pins CA1_P, to one or more second CA pins CA2_P in one direction. The CA training signal may be provided to the DUT through the second CA training path 1331b, rather than the CA conversion circuit 1310 according to the some example embodiments.

The second write training path 1332b and the second read training path 1333b may be connected to a first switch SW1b and a second switch SW2b. Pins to be respectively connected to each training path may be mapped through the first switch SW1b and the second switch SW2b.

The first switch SW1b may be connected to one or more first DQ pins DQ1_P to provide a write training signal, provided from one or more first DQ pins DQ1_P, to the second write training path 1332b, or to provide a read training signal, provided from the second read training path 1333b, to the one or more first DQ pins DQ1_P.

The second switch SW2b may be connected to one or more second DQ pins DQ2_P to provide a read training signal provided from one or more second DQ pins DQ2_P to the second read training path 1333b, or to provide a write training signal provided from the second write training path 1332b to one or more second DQ pins DQ2_P.

The second write training path 1332b may receive a write training signal classified as a first NRZ signal through the first interface circuit 1100 including pins, and expand the write training signal by a number of bits mapped to the number of symbols required from the DUT. The second write training path 1332b may map the expanded write training signal into I groups (where I is a positive integer) and symbols and provide mapped write training signal to the second interface circuit 1200.

The I groups may be defined for a plurality of pins (for example, second DQ pins) included in the second interface circuit 1200 and mapped to the write training signal. For example, the plurality of second DQ pins may be grouped into I groups.

The test device may have a limit on the number of assigned channels. In this regard, grouping may be applied to apply a large amount of training data at once. For example, when there are 11 second DQ pins, the 11 pins may be grouped into 4 groups and the same write training signal may be applied to each group.

A size of the write training signal applied to each group may be defined as the product of the number of groups, a burst length BL, and the number of bits mapped to a single symbol. The size defined by the product may be equal to a size of the write training signal applied to the test device. For example, when the number of groups is 4, the burst length is 16, and 2 bits are mapped to 1 symbol, 128 bits of write training signal may be applied to each group.

The second read training path 1333b may receive a read training signal, classified as a PAM signal, through the second interface circuit 1200 including pins and provide the received read training signal to the first interface circuit 1100 by reading the read training signal J times (where J is a positive integer). The number of reads J may be set or defined based on the bit size of the read training signal and/or the number of pins mapped for training on the first DQ pin.

The second error training path 1334b may receive a second error training signal generated from the DUT for training through one or more second error pins ERR2_P and convert the second error training signal into the first error training signal. The second error training path 1334b may provide the first error training signal to the first interface circuit through the one or more first error pins ERR1_P.

As an example, some example embodiments in which 160 symbols of read training signal are received from the DUT. The second switch SW2b maps one or more second DQ pins DQ2_P to the second read training path 1333b, and the first switch SW1b maps one or more first DQ pins DQ1_P to the second read training path 1333b. The second read training path 1333b may convert 160 symbols into 320 bits, split the 320 bits, and provide the split bits to the one or more mapped first DQ pins DQ1_P over J times.

According to the above-described some example embodiments, the second training circuit 1330b may enable the test device to perform training operations more efficiently by providing paths and mappings for training signals separately from normal operation.

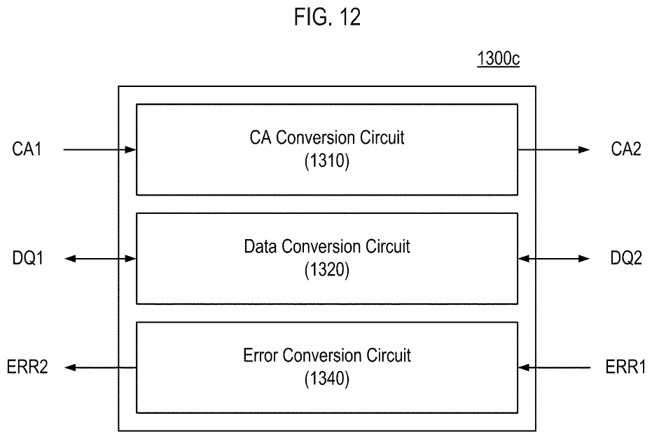

FIG. 12 is a block diagram of a conversion circuit according to some example embodiments.

Referring to FIG. 12, the conversion circuit 1300c according to some example embodiments may further include an error conversion circuit 1340 converting an error detection signal in addition to the CA conversion circuit 1310 and the data conversion circuit 1320 according to the above-described some example embodiments (for example, FIGS. 2 to 9).

The error conversion circuit 1340 may receive a first error detection signal ERR1 classified as a PAM signal through the second interface circuit 1200 according to the above-described some example embodiments (for example, FIGS. 1 and 2). The first error detection signal ERR1 may be configured to indicate whether there is an error in at least one of the CA signal CA2 or the data signal DQ2. The first error detection signal ERR1 may be a signal generated and provided from the DUT when an error is detected in the DUT through a test.

The error conversion circuit 1340 may convert the first error detection signal ERR1 into a second error detection signal ERR2 classified as a first NRZ signal. According to some example embodiments, the error conversion circuit 1340 may convert a PAM-modulated signal into an NRZ-modulated signal to output the second error detection signal ERR2.

Alternatively, when a speed of the first error detection signal ERR1 on the DUT side is lower than a speed required by the test device, the error conversion circuit 1340 may up-convert the speed of the first error detection signal ERR1 and output the signal having the up-converted speed as the second error detection signal ERR2.

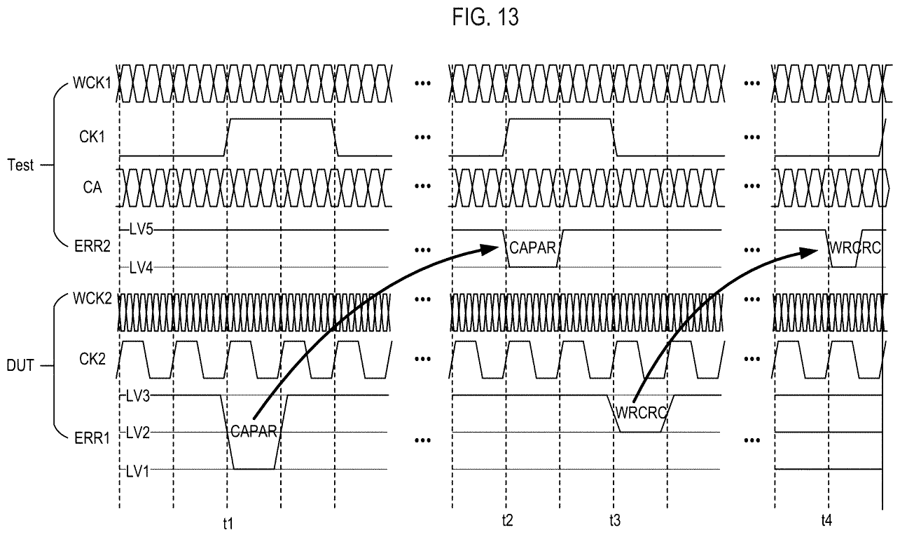

FIG. 13 is a waveform diagram illustrating an example operation of an error conversion circuit of FIG. 12 according to some example embodiments.

Referring to FIG. 13, the test device according to the above-described some example embodiments may operate based on a first write clock WCK1, a first clock CK1, a CA signal CA, and a second error detection signal ERR2, and the DUT may operate based on a second write clock WCK2, a second clock CK2, and a first error detection signal ERR1. As an example, in some example embodiments in which the test device operates at a relatively lower speed than the DUT, the first write clock WCK1 and the first clock CK1 are illustrated as having a lower speed (or a lower frequency) than the second write clock WCK2 and the second clock CK2. A frequency of each signal is merely set as an example.

When an example is provided in which the first error detection signal ERR1 is PAM3-modulated, the first error detection signal ERR1 may have three logic levels, as illustrated. When an example is provided in which the second error detection signal ERR2 is NRZ-modulated, the second error detection signal ERR2 may have two logic levels, as illustrated.

As an error is detected in the CA signal CA, the DUT may transmit a first error detection signal ERR1 at time t1. The first error detection signal ERR1 may drop from a third level to a first level for a certain period from time t1. An example is provided in which the first level of the first error detection signal ERR1 represents CA parity (CAPAR).

The error conversion circuit 1340 may receive the first error detection signal ERR1 of PAM3 and convert the received first error detection signal ERR1 into a second error detection signal ERR2 of NRZ. As a result, the test device may receive the second error detection signal ERR2 having two levels (a fourth level and a fifth level) and two bits at time t2.

Then, as an error in write data is detected, the first error detection signal ERR1 is transmitted at time t3. The first error detection signal ERR1 may drop from the third level to the second level for a certain period from time t3. An example is provided in which the second level of the first error detection signal ERR1 represents write CRC (WRCRC).

The error conversion circuit 1340 may receive the first error detection signal ERR1 of PAM3 and convert the received first error detection signal ERR1 into a second error detection signal ERR2 of NRZ. As a result, the test device may receive the second error detection signal ERR2 having two levels (the fourth level and the fifth level) and two bits at time t4.

According to the above-described some example embodiments, the error conversion circuit 1340 may convert an error detection signal based on the test and provide the converted error detection signal depending on a data rate and a modulation scheme required by the test device. As a result, the error conversion circuit 1340 may provide an interface function for the error detection signal.

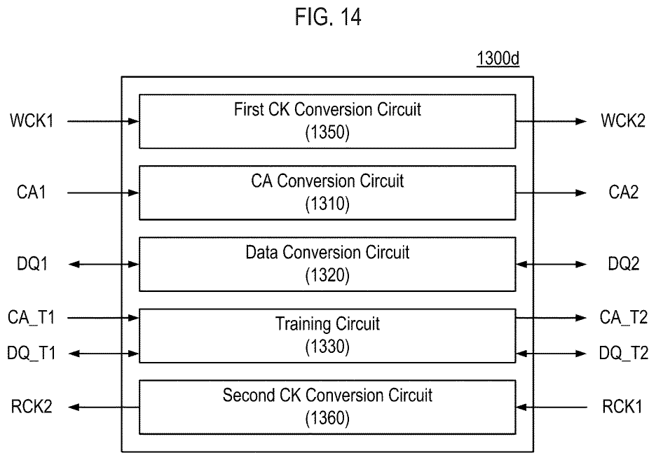

FIG. 14 is a block diagram of a conversion circuit according to some example embodiments.

Referring to FIG. 14, a conversion circuit 1300d according to some example embodiments may further include a first clock conversion circuit 1350 and a second clock conversion circuit 1360 in addition to the CA conversion circuit 1310, the data conversion circuit 1320, and the training circuit 1330 according to the above-described some example embodiments.

The first clock conversion circuit 1350 may be configured to provide a conversion operation on a write clock provided from the test device to the DUT. The first clock conversion circuit 1350 may receive a first write clock WCK1 from the test device and up-convert a speed of the first write clock WCK1 to match a data speed required by the DUT. Accordingly, the second write clock WCK2 having a speed, up-converted through the first clock conversion circuit 1350, may be output to the test device.

The second clock conversion circuit 1360 may be configured to provide a conversion operation on the read clock provided from the DUT to the test device. The second clock conversion circuit 1360 may receive a first read clock RCK1 from the DUT and down-convert a speed of the first read clock RCK1 to match a data speed required by the test device. Accordingly, the second read clock RCK2 having a speed, down-converted through the second clock conversion circuit 1360, may be output to the test device.

According to the above-described embodiments, the conversion circuit 1300d may provide the write clock and read clock for testing the test device, converted to match the data speeds required by the test device and the DUT. As a result, the conversion circuit 1300d may provide an interface function for testing clocks.

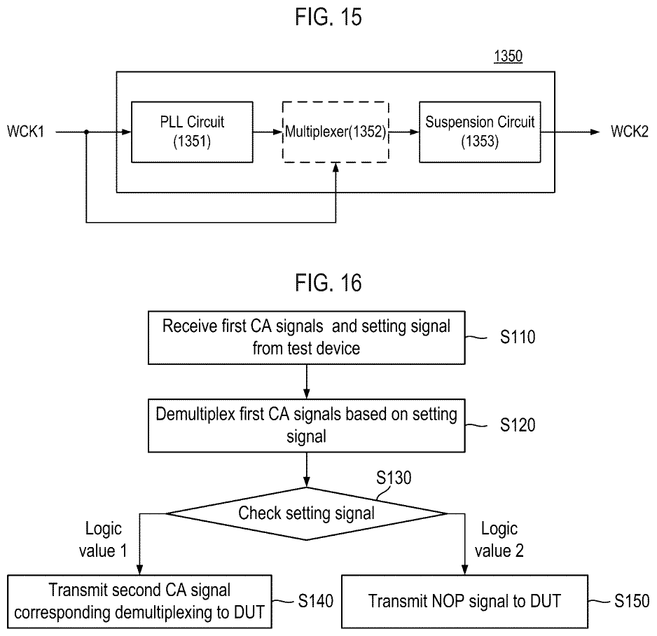

FIG. 15 is a block diagram of a first clock conversion circuit according to some example embodiments.

Referring to FIG. 15, the first clock conversion circuit 1350 according to some example embodiments may include a phase-locked loop (PLL) circuit 1351, a multiplexer 1352, and a suspension circuit 1353.

The PLL circuit 1351 may receive a first write clock WCK1 from the test device and multiply and fix a frequency of the first write clock WCK1 to a target frequency. According to some example embodiments, the target frequency based on the multiplication may be variously set depending on the speed of a write clock required by the DUT. The speed of the first write clock WCK1 may be up-converted and provided to the DUT through the PLL circuit 1351.

The multiplexer 1352 may be connected between the PLL circuit 1351 and the suspension circuit 1353. The multiplexer 1352 may receive the first write clock WCK1 applied to the PLL circuit 1351, and may be configured to perform a bypass function on the PLL circuit 1351. Accordingly, the first write clock WCK1 may have a speed converted through the PLL circuit 1351, or the first write clock WCK1 may be applied to the suspension circuit 1353 through the multiplexer 1352 as an original signal without modification.

The multiplexer 1352 may be controlled based on the setting of the above-described register 1312 shown in FIG. 3. According to some example embodiments, the multiplexer 1352 may be omitted.

The suspension circuit 1353 may be configured to support a suspend function for enable control during a test operation (or a training operation) through the test device. For example, the suspension circuit 1353 may support a suspend function to fix the second write clock WCK2 signal to a logic high (or low) level.

The second write clock WCK2 may be output to the DUT through the suspension circuit 1353. The second write clock WCK2 may have a speed up-converted through the PLL circuit 1351. When the write clock is disabled according to the suspend function, the second write clock WCK2 may be output at a fixed specific level.

FIG. 16 is a flowchart illustrating a method of converting a CA signal of an interface chip according to some example embodiments.

Referring to FIG. 16, in operation S110, an interface chip may receive a plurality of first CA signals, classified as first NRZ signals, and a setting signal classified, as a sideband signal, from a test device. For example, the interface chip may receive a plurality of first CA signals through N channels.

In operation S120, the interface chip may demultiplex the plurality of first CA signals based on the setting signal. A second CA signal, classified as a second NRZ signal, may be generated in response to the demultiplexing. According to some example embodiments, when the setting signal indicates a second logic value, the interface chip may internally set mode operation of the demultiplexing based on a register. Then, the interface chip may perform demultiplexing based on the set mode.

In operation S130, the interface chip may check a logic state of the setting signal.

When the setting signal indicates a first logic value, the flow proceeds to operation S140 in which the interface chip may transmit the second CA signal to a DUT.

Alternatively, when the setting signal indicates a second logic value, the flow proceeds to operation S150 in which the interface chip may transmit a NOP signal to the DUT. The interface chip may set the mode of demultiplexing.

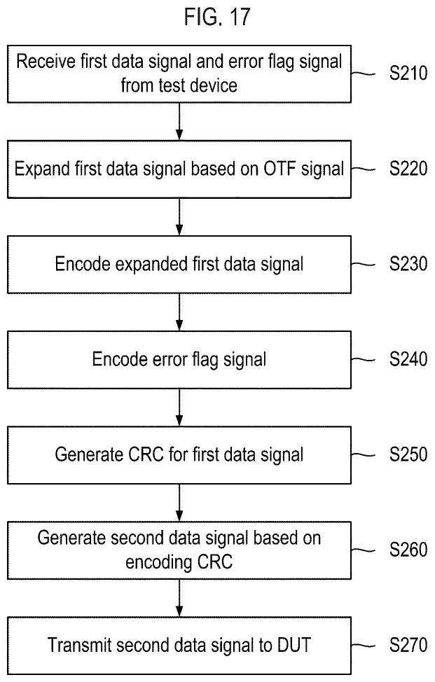

FIG. 17 is a flowchart illustrating a method of converting a write data signal of an interface chip according to some example embodiments.

Referring to FIG. 17, in operation S210, an interface chip may receive a first data signal (for example, write data), classified as a first NRZ signal, and an error flag signal from a test device.

In operation S220, the interface chip may expand the first data signal based on an OTF signal classified as a sideband signal. In operation S220, data may be copied and/or inverted for expansion.

In operation S230, the interface chip may encode the expanded first data signal.

In operation S240, the interface chip may encode the error flag signal. For example, the encoding may map each signal bit to a symbol based on xbys.

In operation S250, the interface chip may generate a CRC for the expanded first data signal. For example, operations S230 and S250 may be performed in parallel to operation S240 in which the error flag signal is encoded.

In operation S260, the interface chip may generate a second data signal based on encoding the CRC. The second data signal may include the encoded first data signal, the error flag signal, and the CRC.

In operation S270, the interface chip may transmit a second data signal to the DUT.

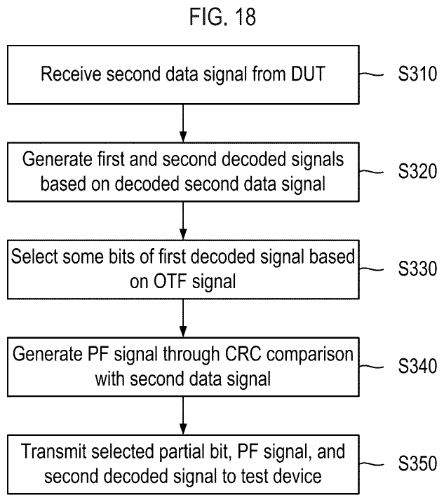

FIG. 18 is a flowchart illustrating a method of converting a read data signal of an interface chip according to some example embodiments.

Referring to FIG. 18, in operation S310, an interface chip may receive a second data signal (for example, read data) from a DUT.

In operation S320, the interface chip may decode a second data signal to generate a first decoded signal and a second decoded signal. For example, the decoding may map each signal symbol to a bit based on xbys.

In operation S330, the interface chip may select some bits of the first decoded signal based on an OTF signal classified as a sideband signal.

In operation S340, the interface chip may generate a PF signal through a CRC comparison with some symbols (for example, a second symbol).

In operation S350, the interface chip may transmit the selected bits, the PF signal, and the second decoded signal to the test device.

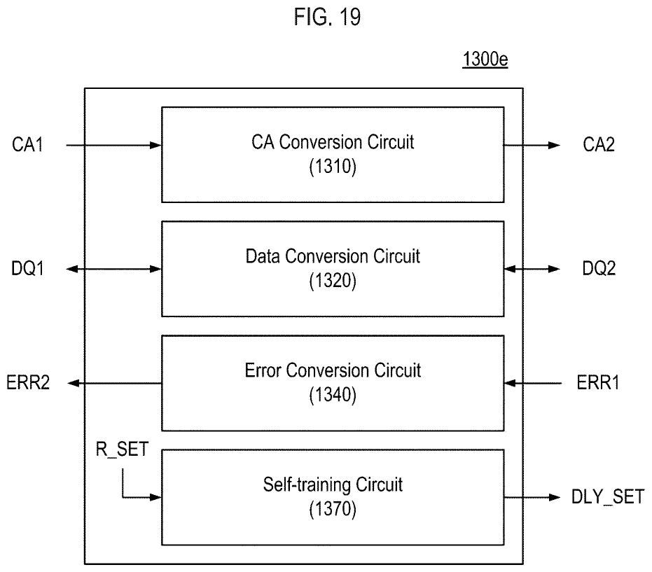

FIG. 19 is a block diagram of a conversion circuit according to some example embodiments.

Referring to FIG. 19, a conversion circuit 1300e according to some example embodiments may further include a self-training circuit 1370 in addition to the CA conversion circuit 1310, the data conversion circuit 1320, and the error conversion circuit 1340 according to the above-described embodiments.

The self-training circuit 1370 may be configured to perform training autonomously. The term “autonomously” may mean that signal training may be performed without control of the test device.

According to some example embodiments, the self-training circuit 1370 may operate based on a register setting signal R_SET. The register setting signal R_SET may be generated through the register according to the above-described some example embodiments. The register setting signal R_SET may include various setting/control signals for the self-training operation.

The self-training circuit 1370 may perform and control phase interpolation (PI) for data shift and phase adjustment of various signals converted through an interface chip, and may autonomously determine pass or fail states of timing errors. When a failure occurs, the self-training circuit 1370 may continue to perform data shift and/or phase adjustment until a pass occurs.

The self-training circuit 1370 may generate a delay setting signal DLY_SET according to data shift and/or phase adjustment. The delay setting signal DLY_SET may include the amount of data shift and/or phase adjustment to be applied to each signal (for example, CA signals CA1 and CA2, data signals DQ1 and DQ2, error flag signals, and error detection signals ERR1 and ERR2), or the like).

The self-training circuit 1370 according to the above-described embodiments may reduce timing errors by identifying an optimal delay that ensures a pass, and applying the optimal delay to a signal.

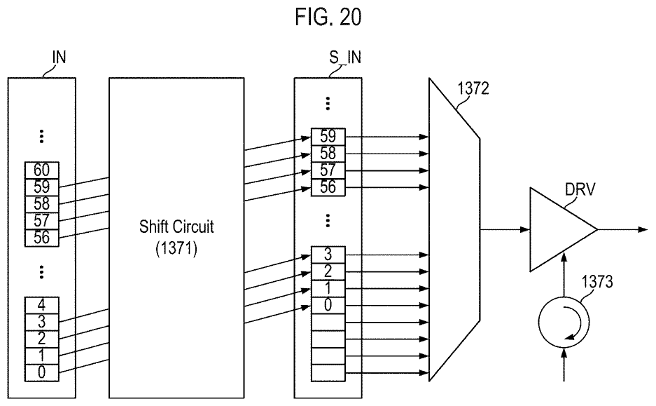

FIG. 20 is a diagram illustrating an operation of a self-training circuit of FIG. 19 according to some example embodiments.

Referring to FIG. 20, a self-training circuit 1370 according to some example embodiments may include a shift circuit 1371, a multiplexer 1372, and a PI 1373.

The shift circuit 1371 may be configured to receive input data IN (for example, a bit sequence) and shift the input data IN in units of UIs. For example, the shift circuit 1371 may shift the input data IN by 4 UIs as illustrated in FIG. 20 and output shifted data S_IN. Each number of the input data IN represents an index of each bit, and the shift may involve a 0th bit shifted to a 5th bit and a 1st bit shifted to a 6th bit.

The multiplexer 1372 may receive the shifted data S_IN, and may select and output at least a portion of the shifted data S_IN to a driver DRV. The driver DRV may be included in the first interface circuit 1100 and/or the second interface circuit 1200 according to the above-described embodiments, and may be configured to drive the data finally and output the driven data to a test device or a DUT.

The PI 1373 may be configured to adjust a phase of data applied to the driver DRV. At least a portion of the shifted data S_IN is applied to the driver DRV through the multiplexer 1372, so that the PI 1373 may adjust the phase of the transitioning data S_IN in units of at least some units.

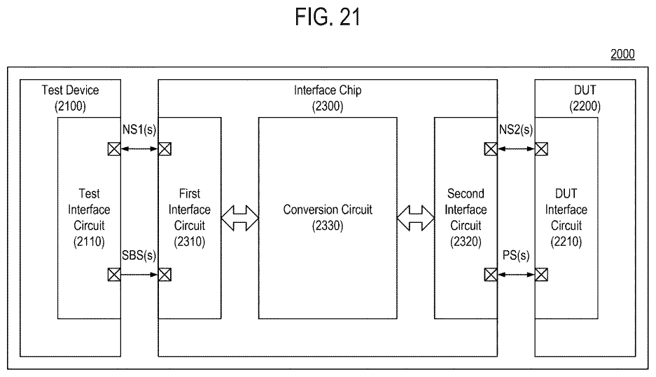

FIG. 21 is a diagram illustrating a test system according to some example embodiments.

Referring to FIG. 21, a test system 2000 according to some example embodiments may include a test device 2100, a DUT 2200, and an interface chip 2300.

The test device 2100 may include a test interface circuit 2110 transmitting and receiving signals to and from the interface chip 2300. The test interface circuit 2110 may include a plurality of pins for transmitting and receiving signals to and from the interface chip 2300. The test device 2100 may be connected to the interface chip 2300 through a plurality of conductive lines to transmit and receive signals for testing.

According to some example embodiments, the test interface circuit 2110 may transmit or receive a first NRZ signal NS1s modulated by NRZ, or transmit a sideband signal SBS(s) generated in the test device 2100 to control the interface chip 2300.

The test device 2100 may generate signals having test patterns for testing (for example, a CA signal, a write data signal, or the like) and may use the generated signals for testing. The test device 2100 may receive a signal based on a test result.

The DUT 2200 may include a DUT interface circuit 2210 transmitting and receiving signals to and from the interface chip 2300. According to some example embodiments, the DUT interface circuit 2210 may transmit or receive a second NRZ signal NS2s modulated by NRZ, or transmit or receive a PAM signal PS(s) modulated by PAM from the DUT 2200.

The DUT 2200 may include various semiconductor devices. For example, the DUT 2200 may be a volatile memory, such as a static random access memory (SRAM) or a dynamic random access memory (DRAM), or a nonvolatile memory such as a flash memory or a resistive random access memory (RRAM).

The DUT 2200 may be applied with various signals for testing through the interface chip 2300, and may apply signals corresponding to a result based on the test through the interface chip 2300.

The interface chip 2300 may be configured or operate according to the above-described embodiments. According to some example embodiments, the interface chip 2300 may transmit or receive a first NRZ signal NS1(s) through the first interface circuit 2310, or receive a sideband signal SBSs through the first interface circuit 2310. Also, the interface chip 2300 may transmit or receive a second NRZ signal NS2(s) and a PAM signal PSs through the second interface circuit 2320. The interface chip 2300 may provide conversion between the first NRZ signal NS1(s) and the second NRZ signal NS2(s) or between the first NRZ signal NS1(s) and the PAM signal PS(s) through the conversion circuit 2330.

According to the above-described embodiments, the test system 2000 may provide a bidirectional interface between the test device 2100 and the DUT 2200, supporting or requiring different data speeds and/or modulation schemes, allowing the DUT 2200 to be tested even with test devices 2100 having different specifications.

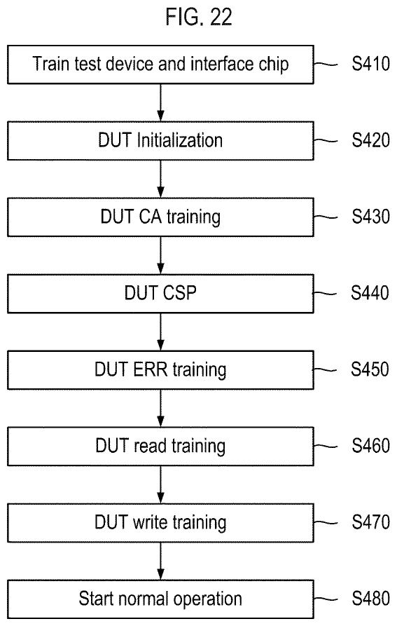

FIG. 22 is a flowchart of a DUT-side training operation of the test system of FIG. 21 according to some example embodiments.

Referring to FIG. 22, in operation S410, a test system may perform training between a test device and an interface chip. In operation S410, the test device and the interface chip may participate in the training to synchronize signals with the training on a signal from the test device to the interface chip. According to some example embodiments, in operation S410, CA training, CSP (command start point) setting, write training, read training, and error training for the test device may be performed.

In operation S420, the test system may initialize the DUT. The initialization may be performed to set initial setting of the DUT before training the DUT. In operation S420, the DUT may set power, parameters related to initialization, and a register.

In operation S430, the test system may train the CA signal for the DUT.

In operation S440, the test system may set a command start point (CSP), a start point for a clock signal for a command.

In operation S450, the test system may perform error detection signal training (ERR training) on the DUT.

In operation S460, the test system may perform read training on the DUT. For example, the test system may synchronize signals related to the read operation on the DUT through the training circuit according to the above-described embodiments (for example, FIGS. 10 and 11).

In operation S470, the test system may perform write training on the DUT. For example, the test system may synchronize signals related to the write operation on the DUT through the training circuit according to the above-described embodiments (for example, FIGS. 10 and 11).

In operation S480, the test system may perform a normal operation. After synchronizing the signals through operations S410 to S470, the test system may perform a normal operation for testing according to the above-described embodiments.

For example, based on the normal operation for testing in operation S480 and in the event that the conversion circuit 2330 provides an error flag signal EF (e.g., see FIG. 9) through the first interface 2310 to the test device 2100 based on the testing, the test device 2100 may determine that the DUT 2200 associated with the error flag signal EF may be categorized and/or upgraded and/or downgraded. For example, based on the error flag signal EF, some DUTs may be recalled; alternatively, based on the error flag signal EF, some DUTs may be provided to some customers but not to other customers. Alternatively or additionally, the DUT may be dispositioned based on the error flag signal EF. For example, depending on the error flag signal EF, the DUT may be graded and/or scrapped or upgraded and/or dispositioned to a particular product or application. Alternatively or additionally, in some example embodiments, the DUT may be re-trained by repeating steps S410 through S470 in FIG. 22, and the normal operation for a testing operation may be performed again on the DUT so that a PASS test result may be obtained due to the re-training. Example embodiments are not limited thereto.

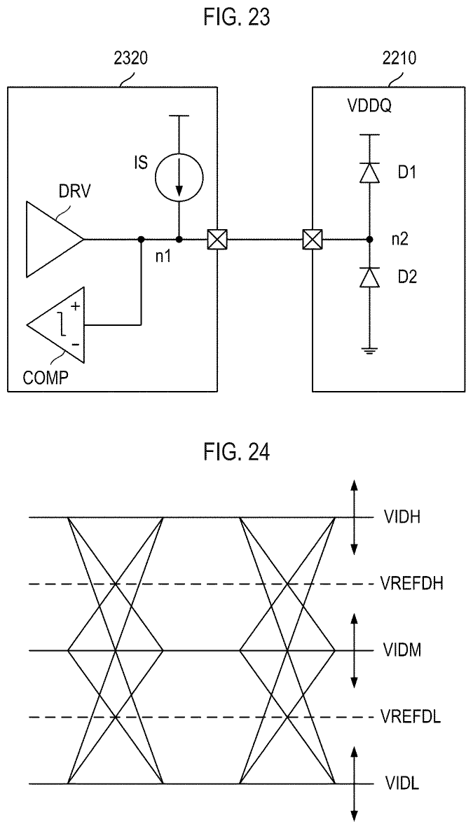

FIG. 23 is a diagram illustrating an open test operation of a test system according to some example embodiments.

Referring to FIG. 23, the second interface circuit 2320 (e.g., see FIG. 21) according to some example embodiments may include a current source IS, a driver DRV, and a comparator COMP. A DUT interface circuit 2210 may include a first diode D1, corresponding to a pull-up diode applied with VDDQ, and a second diode D2 corresponding to a pull-down diode connected to ground.

The current source IS and driver DRV may be configured to apply a test signal for an open test to a side of the DUT interface circuit 2210 through a first node n1. A voltage level corresponding to the applied test signal may be exhibited at a second node n2 to which an anode of a first diode D1 and a cathode of a second diode D2 are connected. The voltage level may be applied to an input of the comparator COMP through the first node n1, and the comparator COMP may compare the voltage level with a reference level.

The comparator COMP may determine pass or failure based on a result of the comparison result between the voltage level and the reference level. When the test passes, DUT pins are in normal contact. When the test fails, there is an issue with the contact.

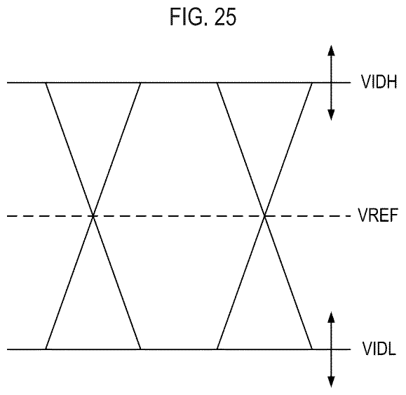

FIGS. 24 and 25 are diagrams illustrating signal level adjustment operations of a test system according to some example embodiments.

Referring to FIGS. 24 and 25, a test system according to some example embodiments may adjust voltage levels of an NRZ-modulated signal and/or a PAM-modulated signal through each interface circuit (for example, the first interface circuit, the second interface circuit, the test interface circuit, and/or the DUT interface circuit according to the above-described embodiments). Although FIG. 24 is based on a PAM3 signal, some example embodiments are not limited thereto.

The PAM3 signal may have three voltage levels as illustrated in FIG. 24, and two reference voltages VREFDH and VREFDL may be defined. An NRZ signal may have two voltage levels as illustrated in FIG. 25, and a single reference voltage VREF may be defined.

For example, the test system may control voltage levels of the NRZ signal and the PAM signal by controlling the high voltage level VIDH with respect to a pull-up termination (or a pull-down termination). Alternatively, the test system may proportionally control a mid voltage level VIDM and/or a low voltage level VIDH with respect to the high voltage level VIDH based on a termination situation.

As set forth above, according to some example embodiments, an interface chip for providing interfacing between a test device and a device under test (DUT) and a test system including the same may be provided.

One or more of the elements disclosed above may include or be implemented in processing circuitry such as hardware including logic circuits; a hardware/software combination such as a processor executing software; or a combination thereof. For example, the processing circuitry may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, an application-specific integrated circuit (ASIC), etc.

While some example embodiments have been shown and described above, it will be apparent to those skilled in the art that modifications and variations could be made without departing from the scope of the present inventive concepts as defined by the appended claims.

What is claimed is:

1. An interface chip comprising:
a first interface circuit connected to a test device, the first interface circuit configured to provide an interface for a first non-return to zero (NRZ) signal and a sideband signal for the test device;
a second interface circuit connected to a device under test (DUT), the second interface circuit configured to provide an interface for a second NRZ signal and a pulse amplitude modulation (PAM) signal for the DUT; and
a conversion circuit connected to the first interface circuit and the second interface circuit, the conversion circuit configured to provide conversion between the first NRZ signal and the second NRZ signal and between the first NRZ signal and the PAM signal based on the sideband signal.

2. The interface chip of claim 1, wherein
the first interface circuit is configured to receive a plurality of first command address (CA) signals provided as the first NRZ signal, and
the conversion circuit is configured to demultiplex the plurality of first CA signals based on a setting signal received as the sideband signal, and provide a second CA signal as the second NRZ signal to the second interface circuit in response to demultiplexing by the conversion circuit.

3. The interface chip of claim 2, wherein the conversion circuit is configured to
provide the second CA signal to the second interface circuit based on the setting signal indicating a first logic value,
provide a no-operation (NOP) signal instructing the DUT to operate in an idle state to the second interface circuit based on the setting signal indicating a second logic value, and
set the demultiplexing.

4. The interface chip of claim 3, wherein the conversion circuit is configured to
set the demultiplexing to a 1:1 mode based on a data rate required by the second CA signal being less than K, wherein K is a real number, and
set the demultiplexing to an N: 1 mode based on the data rate being greater than or equal to K, wherein N is a number of the plurality of first CA signals.

5. The interface chip of claim 1, wherein
the first interface circuit is configured to transmit a first data signal as the first NRZ signal to the test device or receive the first data signal from the test device as the first NRZ signal, and transmit an error flag signal to the test device or receive the error flag signal from the test device, and
the second interface circuit is configured to transmit a second data signal as the PAM signal to the DUT or receive the second data signal as the PAM signal from the DUT.

6. The interface chip of claim 5, wherein the conversion circuit is configured to
expand the first data signal received from the test device based on an on-the-fly (OTF) signal received as the sideband signal to generate an expanded first data signal,
generate a cyclic redundancy check (CRC) for the first data signal received from the test device, and
provide the second data signal to the second interface circuit based on encoding the expanded first data signal, the error flag signal received from the test device, and the CRC.

7. The interface chip of claim 5, wherein the conversion circuit is configured to
decode a plurality of first symbols of the second data signal received from the DUT to obtain a first decoded signal,
select a portion of bits of the first decoded signal based on an on-the-fly (OTF) signal received as the sideband signal to generate a selected portion of bits, and
provide the selected portion of bits to the first interface circuit.

8. The interface chip of claim 7, wherein the conversion circuit is configured to
generate a pass/fail (P/F) signal by performing a CRC comparison on a plurality of second symbols of the second data signal received from the DUT, and
provide the P/F signal to the first interface circuit.

9. The interface chip of claim 8, wherein the conversion circuit is configured to
decode a third symbol corresponding to the error flag signal in the second data signal received from the DUT to obtain a second decoded signal, and
provide the second decoded signal to the first interface circuit.

10. The interface chip of claim 1, further comprising
a training circuit configured to provide a write training path for write training of the DUT and a read training path for read training of the DUT.

11. The interface chip of claim 10, wherein
the write training path is configured to
receive a write training signal as the first NRZ signal through the first interface circuit,
expand the write training signal by a number of bits mapped to a number of symbols required by the DUT to provide an expanded write training signal, and
map the expanded write training signal into I groups to provide a mapped write training signal to the second interface circuit, wherein I is a positive integer, and
the I groups are defined for a plurality of pins included in the second interface circuit and mapped to the write training signal.

12. The interface chip of claim 10, wherein the read training path is configured to
receive a read training signal as the PAM signal through the second interface circuit, and
provide the read training signal to the first interface circuit by reading the read training signal J times, wherein J is a positive integer.

13. The interface chip of claim 1, wherein
the second interface circuit is configured to receive a first error detection signal as the PAM signal from the DUT,
the first error detection signal is configured to indicate whether an error has been detected in at least one of a command address (CA) signal or a data signal received from the DUT, and
the conversion circuit is configured to convert the first error detection signal into a second error detection signal classified as the first NRZ signal.

14. An interface chip comprising:
a command address (CA) conversion circuit configured to receive a setting signal and a plurality of first CA signals which are non-return to zero (NRZ) signals from a test device, demultiplex the plurality of first CA signals based on the setting signal, and output a second CA signal to a device under test (DUT) in response to demultiplexing by the CA conversion circuit; and
a data conversion circuit configured to
transmit a first data signal corresponding to the plurality of first CA signals and an error flag signal to the test device, the first data signal being an NRZ signal, or receive the first data signal, the error flag signal and an on-the-fly (OTF) signal from the test device,
transmit a second data signal corresponding to the plurality of first CA signals to the DUT, the second data signal being a pulse amplitude modulated (PAM) signal, or receive from the DUT the second data signal, and
provide conversion between the first data signal, the error flag signal, and the second data signal based on the OTF signal.

15. The interface chip of claim 14, wherein the CA conversion circuit comprises:
a demultiplexer configured to output the second CA signal based on the demultiplexing; and
a multiplexer configured to select the second CA signal based on the setting signal indicating a first logic value, and select a no-operation (NOP) signal as an output of the CA conversion circuit to the DUT instructing the DUT to operate in an idle state based on the setting signal indicating a second logic value.

16. The interface chip of claim 15, further comprising
a register configured to receive the setting signal and set the demultiplexing based on the setting signal indicating the second logic value.

17. The interface chip of claim 16, wherein the register is configured to
set the demultiplexing to a 1:1 mode based on a data rate required by the second CA signal being less than K, wherein K is a real number, and
set the demultiplexing to an N: 1 mode based on the data rate being greater than or equal to K, wherein N is a number of the plurality of first CA signals.

18. The interface chip of claim 14, wherein the data conversion circuit is configured to
expand the first data signal received from the test device based on the OTF signal to provide an expanded first data signal,
generate a cyclic redundancy check (CRC) for the first data signal, and
output the second data signal based on encoding the expanded first data signal, the error flag signal received from the test device, and the CRC.

19. The interface chip of claim 14, wherein the data conversion circuit is configured to
decode a plurality of first symbols of the second data signal received from the DUT to obtain a first decoded signal,
select a portion of bits of the first decoded signal based on the OTF signal to generate a selected portion of bits, and
output the selected portion of bits to the test device.

20. A test system comprising:
a test device configured to transmit or receive a first non-return to zero (NRZ) signal for testing, and to transmit a sideband signal for setting modes of operation;
a device under test (DUT) configured to transmit or receive a second NRZ signal and a pulse amplitude modulation (PAM) signal; and
an interface chip connected to the test device and the DUT, the interface chip configured to provide conversion between the first NRZ signal and the second NRZ signal, and between the first NRZ signal and the PAM signal, based on the sideband signal.
